(19) United States
(12) Patent Application Publication
(10) Pub. No.: US 2024/0143881 A1
(43) Pub. Date: May 2, 2024

(54) METHODOLOGY TO INTEGRATE SYNCHRONOUS DOUBLE-CLOCK LATCHES INTO THE DESIGN-FOR-TEST CIRCUITS

(71) Applicant: VIETTEL GROUP, Ha Noi City (VN)

(72) Inventors: Thai Ha Le, Ha Noi City (VN); Ha My Bui, Ha Noi City (VN); Anh Tuan Khong, Song Lo District (VN)

(73) Assignee: VIETTEL GROUP, Ha Noi City (VN)

(21) Appl. No.: 18/358,449

(22) Filed: Jul. 25, 2023

(30) Foreign Application Priority Data
Oct. 31, 2022 (VN) 1-2022-07070

(51) Int. Cl. G06F 30/333; G06F 30/3312

(52) U.S. Cl. CPC G06F 30/333; G06F 30/3312

(57) ABSTRACT

The present invention discloses a DFT (Design for test) methodology to integrate synchronous double-clock latches to synchronize data transferring between two asynchronous clock domains, where the conventional lockup-latches (asynchronous latches) are automatically inserted to connect/combine the two independent asynchronous DFT chains for a more compacted solution. If the asynchronous latches are replaced by the synchronous double-clock ones, the static timing analysis (STA) will check both ends of the latches, therefore, the full combined chain is safe from the setup-hold issues. This method utilizes the automatic flow of asynchronous latches insertion to connect independent DFT chains. Then these conventional latches are replaced by synchronous ones. Both the synthesis, the physical implementation flows in the DFT design and the automatic-test pattern generation (ATPG) scheme have been modified to match these replacements.

### FIELD OF INVENTION

This invention focuses on one aspect, the implementation scheme to integrate the new synchronous latch module into the Design for Test flow.

### RELATED APPLICATION

Design for Test is a significant flow in System on Chip (SoC) design. In manufacturing, it is impossible to ensure that the process is flawless. Such physical defects cause short in the source or drain of the transistor or short with power or ground, open, transition . . . is not related to logical design. This procedure supports designer to check the defects in manufacturing phase without caring about design function. Along with the development of chip, the complication of design is increased, more and more clock domains are used. In consequence, the number of scan chains increases drastically, resulting in design size and power consumption problems of the chips. In order to solve this issue, a methodology to combine/merge DFT (Design for test) chains by using an asynchronous lockup latch to connect data from different clock domains has been widely used. However, since the asynchronous latches are used to combine two independent clock domains, there is no static-timing analysis (STA) right before and after these latches, the combined chains are not guaranteed to meet the setup-and-hold timing requirements. If the asynchronous latches are replaced by the synchronous double-clock ones, the STA checks the timing at both ends of the latches, therefore, the full combined chain is safe from the setup-hold issues.

### BACKGROUND OF THE INVENTION

Sensitive edge in clock domain crossing happens when no timing guarantee at static timing analysis. In other words, two asynchronous clock domains interchanging data may cause the meta-stability. To safely transfer data between two clock domains, designer may need to use some techniques such as hand-shaking or FIFOs. In standard industrial Design for Test implementation flow, the use of asynchronous lockup latches to prevent skew issues when clock edge mixing is common. As mentioned above, the main issue of the asynchronous lockup latches is that these inserted asynchronous latches will not be timing checked because of no associated synchronization clock information and may cause the scan data transfer failure when the skew between two clock domains is unpredictable. The present invention utilizes the automatic flow of synchronous latches insertion to connect independent DFT chains. This proposed flow must ensure that the timing is checked, the equivalent of design between with and without synchronous latch, the correctness of the automatic pattern generator when the logic delay of the double-clock latches is added to connect scan chains.

### SUMMARY OF THE INVENTION

The use of asynchronous lockup latch to merge scan chains in different clock domains is common in Design for Test field. However, this method cannot deal with the phase-sensitive phenomenon between two different clock domains (FIG. 1A). When the active edges of two clocks close together it may cause the meta-stability. Furthermore, the two clock domains are asynchronous and have no timing related between them so the tool cannot optimize to fix the timing violation, which leads the Design for Test not to work properly. To deal with this challenge, the synchronous latch is used instead of the asynchronous lockup latch to allow the two clock domains to communicate and self-balance.

More particularly, the standard Design for Test flow generally inserts the asynchronous lockup latches. This type of cell will be automatically added between two flip-flops 101 and 102 of two clock domains (FIG. 1) and generate the corresponding test patterns to load into the Automatic Test Equipment (ATE). This invention presents the method to integrate a new type of synchronous latch element into the regular Design for Test flow (FIG. 2). This flow is used to replace the asynchronous latches with the synchronous ones in the design, to verify and to generate the appropriate test patterns for Design for Test process.

### BRIEF DESCRIPTION OF THE DRAWINGS

FIG. 1 illustrates the connection of the asynchronous lockup latch between two clock domains CLK1 and CLK2;

FIG. 1A illustrates the metastability when the active edge of CLK1 and CLK2 are close;

FIG. 2 illustrates the synchronous latch between two clock domains CLK1 and CLK2;

FIG. 3 illustrates a regular Design for Test flow using asynchronous lockup latches;

FIG. 4 illustrates the compilation phase in synchronous latch integrated flow;

FIG. 5 illustrates the physical design phase in synchronous latch integrated flow;

FIG. 6 illustrates the test pattern generated phase in synchronous latch integrated flow;

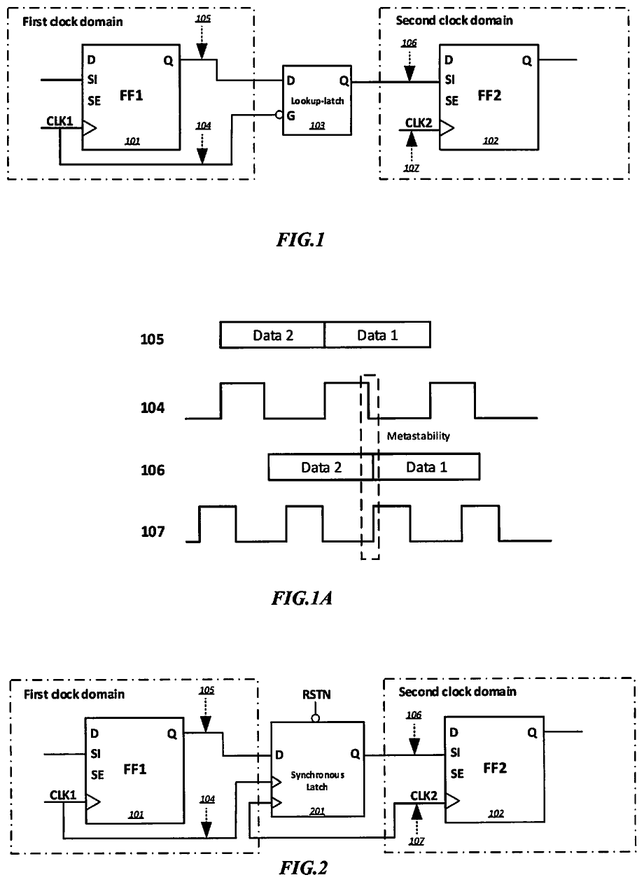

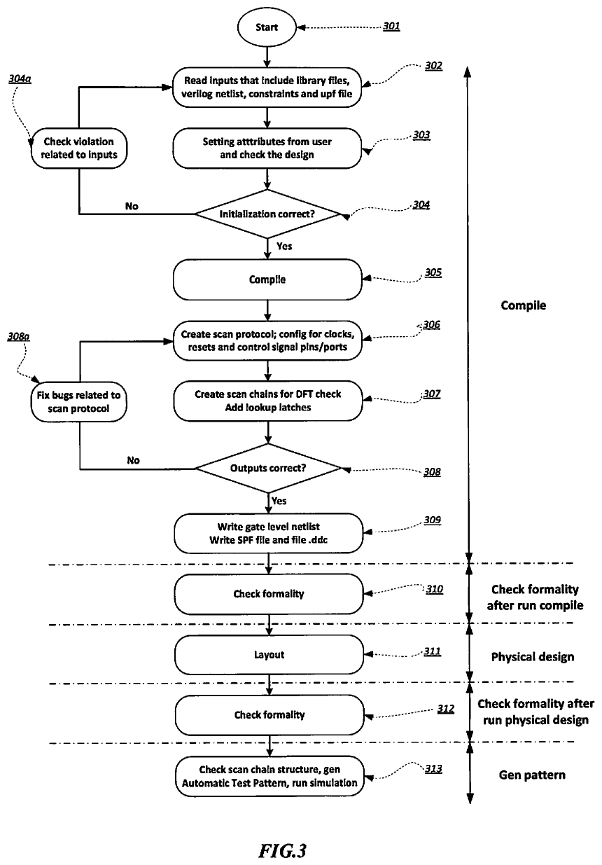

### DETAILED DESCRIPTION OF THE PREFERRED EMBODIMENTS

Typically, to mix scan chains between different clock domains into a single scan chain, the regular flow is automatically inserting asynchronous lockup latches between clock domains. This part presents the regular Design for Test flow using asynchronous lockup latches first, then introduces the solution of using synchronous latches to overcome the drawback of traditional lockup latches.

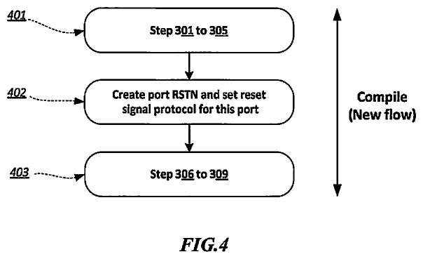

FIG. 3 shows an overall Design for Test flow using asynchronous lockup latches. Steps 301 to 309 are to perform compilation tasks. The 302 step is to load inputs that contain design data, which is a design functional file in RTL or Verilog format, timing constraints, unified power format (UPF) file and libraries of standard cells, hard macros or other modules . . . Step 303 applies user setup like attributes and setting to control the compiler. After loading all of the necessary inputs, step 304 checks the correctness of all setups and input files. Until there are no errors, the initialization is successful. Then, step 305 is to be started. This procedure transforms the design from RTL format to gate-level format. In this step, normal flip-flops without scan signals are replaced by scan flip-flops with scan signals for Design for Test purposes. However, those signals are floated and not connected yet. After this step is completed, the test protocol is defined in step 306. Besides controlling some rules about the number of scan chains, merge chains protocol, length of chains, compress protocol . . . , users need to define the clock signal, scan control signal, reset signal for the shift and capture process for further steps. When the configuration is completed, step 307 is executed to create scan chains. The asynchronous lockup latches are added between two flip-flops of two clock domain pairs in two different scan chains to merge them into one scan chain. After this step, step 308 is to check the correctness of the configuration and to run compile. Then, the configuration step and scan signals definition are to be rechecked if there are any violations. Until the number of violations is zero, the compilation step for Design for Test is completed. All of the necessary output files are written out in step 309. To ensure the scan logic does not affect the function of the design, a formality check between the design in RTL/Verilog level and gate netlist level is run in step 310. If there are any issues, we have to check the compilation process to see if there are any configurations or connections that lead to the failure of the conservation of the design function. After the equivalence is assured, step 311 performs the physical design phase and to executes the formality check to design between the before and after layout in step 312. Step 313 creates patterns, which is the input for the ATE (Automatic Test Equipment).

In order to replace the asynchronous latches with the synchronous latches in Design for Test flow, the invention proposes some changes in regular scan flow in the compilation phase, physical design phase and Automatic Test Pattern Generation phase.

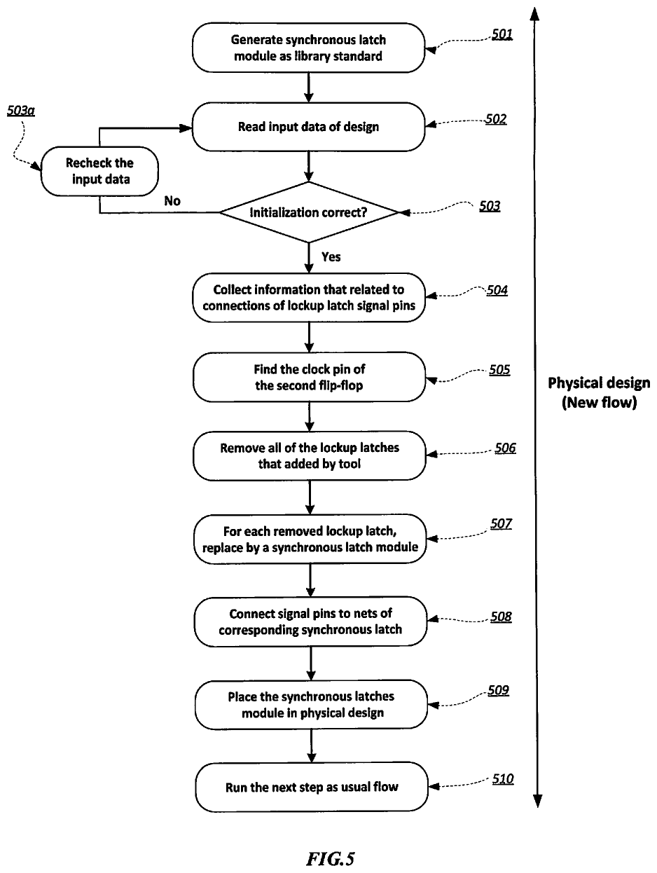

FIG. 4 illustrates the new compilation flow with synchronous latches instead of asynchronous ones. In fact, the synchronous latch is not added in this phase. This flow is nothing but a regular compilation flow (step 401 and step 402) except for one point. The synchronous latches contain a reset signal. In the new compilation flow, make sure that this reset signal is defined and configured in step 402 so the information of this signal can be written to describe the scan behavior for the Automatic Test Pattern Generation phase.

FIG. 5 illustrates the physical design phase in the new flow. To take full advantage of the result of regular Design for Test flow, this invention proposes a solution that reuses the available connections of asynchronous lockup latches which created by tool in the previous step. To be able to use the synchronous latch in the design flow, the synchronous latch must be designed and created all of the necessary input data related to logic, physical, timing . . . as standard 501 that tool can comprehend and perform the optimal algorithm. The double-clock latch must be also designed as a standard cells criterion, the height and the width of the module must be followed by the standard grid for the convenience of the integrated flow. After the libraries for synchronous latch are created properly, all of the design data are loaded in step 502 and the correctness of these input data is checked in step 503. Before replacing the asynchronous latches with the synchronous ones, information of the connectivities of asynchronous lockup latches is collected in step 504. Furthermore, the full name of the clock pin of the flip-flop 102 is also stored. The difference when replacing the asynchronous lockup latch with the synchronous one is that the asynchronous latch is clocked by the first clock domain, which is CLK1. Meanwhile, the synchronous latch is clocked by two clock signals, CLK1 and CLK2. The CLK1 signal has already been connected by reusing wire 104 of the asynchronous lockup latch 103. The CLK2 pin of the synchronous latch is floating. To connect this signal, the CLK2 pin of the second flip-flop is found as step 505 and connected with the corresponding clock pin of the asynchronous. Then, these asynchronous latches are removed in step 506 and replaced by synchronous latch modules in step 507. In step 508, all pins of synchronous latches are connected to create a completed scan structure. Due to in synchronous latch library creation step, we have already set the timing constraints related to CLK1 and CLK2, the tool can optimize the position for the synchronous latch to reduce the skew between two clock domains in step 509. Then, the next step is run as regular flow in step 510.

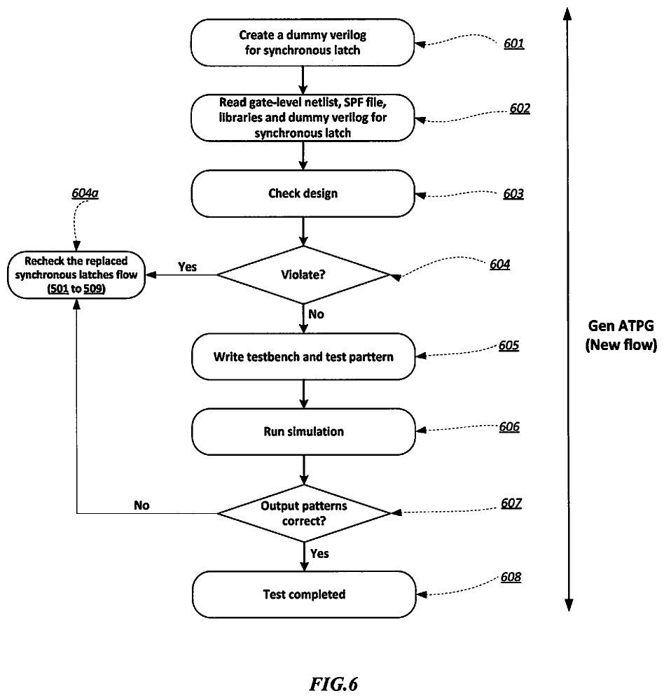

FIG. 6 illustrates a new flow to generate test patterns to test the scan structure. This flow also verifies the accuracy of the synchronous latch replaced process to the scan design. The synchronous latch module includes combinational logic and flip-flops. The tools cannot comprehend and shift bits through combinational logic, resulting in DRC violation when verifying the design. The invention proposes a method that uses a dummy verilog netlist file that describes all of the delay phases of synchronous latch module 601, which means the tool will recognize the synchronous latch as only a delay circuit instead of a complicated combinational logic. All of the necessary inputs are read in step 602 and checked in step 603 until there are no violations in step 604. Step 605 writes the testbench and test pattern. Step 606 runs the simulation in step 606 with the full version of the synchronous latch Verilog, which contains all of the combined elements and sequential cells. This step can detect bugs in the Design for Test flow, especially in the synchronous latch replaced phase. If all of the output patterns are correct in step 607, the test is completed in step 608.

1. An integrated synchronous latch scheme in design for test flow, comprising the following steps: compile, formality after compile, physical layout, formality after layout, generate automatic patterns, wherein:
in the compile step: create and config a reset port so information of this port can be written to describe a scan behavior for an automatic test pattern generation phase
in the physical layout step: create libraries for synchronous latch with all necessary input data related to logic, physical, timing . . . to ensure adding synchronous latches flow will not affect the scan design, then, read necessary inputs, containing information about connections, constraints, attributes and scan structure and check correctness of an initialization; if there are any errors, loop back to a loading inputs step and check input data until a number of violation is zero; after that, add the synchronous latches; previous to running this step, collect information about connections of asynchronous lockup latches before removing them from the design and replacing them with the synchronous latches; then, connect all of scan pins of new two-clock latches to create a completed scan design with new synchronous elements;
in the automatic test pattern generation phase: create a dummy verilog file to describe all of the delay phases of the synchronous latch, wherein a tool recognizes the synchronous latch as only a delay circuit instead of a complicated combinational logic; then check the design, if there is any violation, review the input data till the design is loaded successfully; after that, create a test pattern and a test vector to check manufacturing effects; run simulations, if all of the scan test outputs match, the test pattern generation is completed, else, recheck the previous steps when adding synchronous latches; the simulation phase uses a full version of synchronous latch Verilog, which contains all of the combined elements and sequential cells to ensure the correctness of adding two-clock latch scheme.

2. The integrated synchronous latch scheme in design for test according to claim 1, comprising:
in the physical design step, when creating the library for the synchronous latch, a height of this element must be double a height of a standard site height, similarly, a width of this new type of latch must be double a width of the standard site so the tool can place them in the right position.

3. The integrated synchronous latch scheme in design for test according to claim 1, comprising:
in the physical design step, place all of the elements of the design before creating a power/ground mesh instead of creating the power/ground mesh first to eliminate a contrariety of VDD/VSS nets.

4. The integrated synchronous latch scheme in design for test according to claim 1, comprising:
in the physical design step, when generating the logic library for the synchronous latch, create all of the timing constraints between input data and a first domain clock pin CLK1, the output data and a second clock domain pin CLK2.
